(19) United States
(12) Patent Application Publication
(10) Pub. No.: US 2021/0057235 A1
(43) Pub. Date: Feb. 25, 2021

(54) SUBSTRATE TREATMENT METHOD AND SUBSTRATE TREATMENT DEVICE

(71) Applicant: SCREEN HOLDINGS CO., LTD., Kyoto-shi, Kyoto (JP)

(72) Inventors: Sei NEGORO, Kyoto (JP); Kenji KOBAYASHI, Kyoto (JP)

(73) Assignee: SCREEN Holdings Co., Ltd., Kyoto-shi, Kyoto (JP)

(21) Appl. No.: 16/977,486

(22) PCT Filed: Nov. 22, 2018
(86) PCT No.: PCT/JP2018/043218

§ 371 Date: Sep. 2, 2020

(30) Foreign Application Priority Data
Mar. 5, 2018 (JP) 2018-038993

(51) Int. Cl. H01L 21/67

(52) U.S. Cl. CPC H01L 21/6708

(57) ABSTRACT

TMAH, hydrogen peroxide and water are mixed to make alkaline etching liquid containing TMAH, the hydrogen peroxide and the water and not containing hydrogen fluoride compound. The etching liquid is supplied to a substrate on which a polysilicon film and a silicon oxide film are exposed, thereby etching the polysilicon film while inhibiting etching the silicon oxide film.

### TECHNICAL FIELD

The present invention relates to a substrate processing method and a substrate processing apparatus that process a substrate. Substrates to be processed include a semiconductor wafer, a substrate for a liquid crystal display, a substrate for an optical disc, a substrate for a magnetic disk, a substrate for a magneto-optical disc, a substrate for a photomask, a ceramic substrate, a substrate for a solar cell, a substrate for FPD (a flat panel display) such as an organic EL (electroluminescence) display, and the like, for example.

### BACKGROUND ART

In a manufacturing process of a semiconductor device, a liquid crystal display, etc., a substrate processing apparatus is used which processes a substrate such as a semiconductor wafer or a glass substrate for a liquid crystal display. Patent Literature 1 discloses a substrate processing apparatus that supplies TMAH (tetramethylammonium hydroxide) to the substrate and etches a polysilicon film formed on the substrate.

### CITATION LIST

### Patent Literature

Patent Literature 1: JP 2013-258391 A

### SUMMARY OF INVENTION

### Technical Problem

In a manufacturing process of a semiconductor device, a liquid crystal display, etc., an etching liquid such as TMAH may be supplied to a substrate on which a polysilicon film and a silicon oxide film are exposed so as to etch the polysilicon film while inhibiting etching the silicon oxide film.

A polysilicon film is composed of many minute silicon single crystals. Silicon single crystal shows anisotropy with respect to TMAH. That is, the etching speed when TMAH is supplied to silicon single crystal is different for each crystal plane of silicon (anisotropy of etching). The directions of the crystal planes exposed on the surface of the polysilicon film are various and differ depending on the location of the polysilicon film. Additionally, the directions of the crystal planes exposed on the surface of the polysilicon film are different for each of the polysilicon films.

Since there is anisotropy in silicon single crystal, when the polysilicon film is etched by TMAH, although it is slight, the etching amount of the polysilicon film differs depending on the location of the polysilicon film. Even when a plurality of the polysilicon films are etched by TMAH, although it is slight, the etching amount of the polysilicon film differs depending on the polysilicon film. Even such unevenness of etching may not be acceptable as patterns formed on the substrate are finer and finer.

Thus, an object of the present invention is to provide a substrate processing method and a substrate processing apparatus that are able to uniformly etch a polysilicon film while inhibiting etching a silicon oxide film.

### Solution to Problem

A embodiment of the present invention provides a substrate processing method including an etching liquid making step of making an alkaline etching liquid containing an organic alkali, an oxidizing agent and a water and not containing a hydrogen fluoride compound by mixing the organic alkali, the oxidizing agent and the water, a selectively etching step of supplying the etching liquid made in the etching liquid making step to a substrate on which a polysilicon film and a silicon oxide film are exposed and etching the polysilicon film while inhibiting etching the silicon oxide film.

According to this arrangement, the alkaline etching liquid containing the organic alkali, the oxidizing agent and the water is supplied to the substrate on which the polysilicon film and the silicon oxide film are exposed. The etching liquid is liquid that etches polysilicon and does not or hardly etches silicon oxide. The etching speed of the silicon oxide is smaller than the etching speed of the polysilicon. Thus, it is possible to selectively etch the polysilicon film.

The etching liquid supplied to the substrate touches the surface of the polysilicon film. The surface of polysilicon film is composed of many minute silicon single crystals. The oxidizing agent contained in the etching liquid reacts with the surfaces of the many minute silicon single crystals and forms silicon oxides. Thus, when the oxidizing agent is added to the etching liquid, the etching speed of the polysilicon film gets lower.

However, the oxidizing agent contained in the etching liquid does not uniformly reacts with a plurality of crystal planes of silicon single crystal, but preferentially reacts with one of these crystal planes, which has a higher activation energy. Thus, the etching speed of the crystal plane with high activation energy decreases relatively greatly, and thus the difference in the etching speed between plane directions decreases. It lowers anisotropy of silicon single crystal with respect to the etching liquid. That is, the etching of the silicon single crystals composing the polysilicon film approaches isotropic.

Furthermore, the etching liquid does not contain the hydrogen fluoride compound. The hydrogen fluoride compound reacts with the silicon oxide film and dissolves the silicon oxide film in the etching liquid. The silicon oxide formed by the reaction between the polysilicon film and the oxidizing agent also reacts with the hydrogen fluoride compound and dissolves in the etching liquid. Thus, it is possible to prevent the selectivity (the etching speed of the polysilicon film/the etching speed of the silicon oxide film) from lowering and to prevent the effect due to the oxidizing agent from lowering by removing the hydrogen fluoride compound from the components of the etching liquid. Accordingly, it is possible to uniformly etch the polysilicon film while inhibiting etching the silicon oxide film.

It is noted that the hydrogen fluoride compound is a compound different from the organic alkali (anhydride), the oxidizing agent and the water. The hydrogen fluoride compound represents a compound including BF in its chemical formula. Hydrogen fluoride (BF) is included in the hydrogen fluoride compound.

In the present embodiment, at least one of the following features may be added to the substrate processing method.

The etching liquid making step is a step of making an alkaline liquid consisting of the organic alkali, the oxidizing agent and the water.

According to this arrangement, the alkaline etching liquid containing only the organic alkali, the oxidizing agent and the water and containing no other component is supplied to the substrate on which the polysilicon film and the silicon oxide film are exposed. Thus, it is possible to decrease the difference in the etching speed between plane directions of silicon single crystal and to lower anisotropy of the silicon single crystals composing the polysilicon film with respect to the etching liquid. Accordingly, it is possible to uniformly etch the polysilicon film while inhibiting etching the silicon oxide film.

The substrate includes a laminated film including a plurality of polysilicon films and a plurality of silicon oxide films laminated in a thickness direction of the substrate such that the polysilicon films and the silicon oxide films are alternated and a concave portion recessed from an outermost surface of the substrate in the thickness direction of the substrate and penetrating the plurality of the polysilicon films and the plurality of the silicon oxide films, and the selectively etching step includes a step of supplying the etching liquid at least to an inside of the concave portion.

According to this arrangement, the side surfaces of the polysilicon film and the silicon oxide film included in the laminated film are exposed in the side surface of the concave portion formed in the substrate. The etching liquid is supplied to the inside of the concave portion of the substrate. Thus, the side surfaces of the plurality of the polysilicon films are etched and moved in the plane direction of the substrate (so-called side etching). That is, a plurality of recesses recessed from the side surfaces of the plurality of the silicon oxide films in the plane direction of the substrate are formed in the concave portion.

If the anisotropy of the silicon single crystal with respect to the etching liquid is high, the etching speed of the polysilicon film is slightly different for each polysilicon film. In this case, the depth (the distance in the plane direction of the substrate) of the recess formed in the concave portion is different for each recess. Thus, it is possible to decrease the difference in the etching speed between the plurality of the polysilicon films and to reduce the variation in depth of the recess by including the oxidizing agent in the etching liquid.

The substrate processing method further includes a natural oxide film removing step of supplying an oxide film removing liquid to the substrate and removing a natural oxide film of the polysilicon film before the selectively etching step.

According to this arrangement, the oxide film removing liquid is supplied to the substrate and the natural oxide film of the polysilicon film is removed from the surface layer of the polysilicon film. After that, the etching liquid is supplied to the substrate and the polysilicon film is selectively etched. The natural oxide film of the polysilicon film is mainly composed of silicon oxide. The etching liquid is liquid that etches polysilicon and does not or hardly etches silicon oxide. Thus, it is possible to effectively etch the polysilicon film by removing the natural oxide film of the polysilicon film m advance.

The polysilicon film is a thin film obtained by performing a plurality of steps including a deposition step of depositing polysilicon and a heat treatment step of heating the polysilicon deposited in the deposition step.

According to this arrangement, the polysilicon film, for which the heat treatment step to heat the deposited polysilicon is executed, is etched by the alkaline etching liquid containing the oxidizing agent. When the deposited polysilicon is heated under an appropriate condition, the grain size of the polysilicon increases. Thus, as compared with the case where the heat treatment step is not executed, the silicon single crystals composing the polysilicon film increase in size. It means that the number of the silicon single crystals exposed on the surface of the polysilicon film decreases and the influence of the anisotropy increases. Thus, it is possible to effectively lower the influence of the anisotropy by supplying the etching liquid including the oxidizing agent to such polysilicon film.

The etching liquid making step includes a dissolved oxygen concentration changing step of lowering dissolved oxygen concentration of the etching liquid.

According to this arrangement, the etching liquid the dissolved oxygen concentration of which is lowered is supplied to the substrate. As described above, the oxidizing agent lowers the anisotropy of the silicon single crystals composing the polysilicon film, but decreases the etching speed of the polysilicon film. On the other hand, when the dissolved oxygen concentration of the etching liquid is lowered, the etching speed of the polysilicon film increases. Thus, it is possible to lower the anisotropy of the silicon single crystal while reducing the decrease in the etching speed of the polysilicon film by supplying the substrate with the etching liquid the dissolved oxygen concentration of which is lowered.

The substrate processing method further includes an atmosphere oxygen concentration changing step of lowering oxygen concentration in an atmosphere that is in contact with the etching liquid held by the substrate.

According to this arrangement, the etching liquid is supplied to the substrate in a state where the oxygen concentration in the atmosphere. Thus, the amount of the oxygen dissolved in the etching liquid from the atmosphere decreases and the rise in the dissolved oxygen concentration is reduced. As described above, the oxidizing agent lowers the anisotropy of the silicon single crystals composing the polysilicon film, but decreases the etching speed of the polysilicon film. If the dissolved oxygen concentration of the etching liquid increases, the etching speed of the polysilicon film further decreases. Thus, it is possible to reduce the further decrease in the etching speed by lowering the oxygen concentration in the atmosphere.

The etching liquid making step includes an oxidizing agent concentration changing step of changing concentration of the oxidizing agent in the etching liquid.

According to this arrangement, the concentration of the oxidizing agent in the etching liquid is changed. When the oxidizing agent is added to etching liquid containing the organic alkali and the water even in a very small amount, the difference in the etching speed between the plurality of the crystal planes decreases and the anisotropy of the silicon single crystals composing the polysilicon film is lowered. The difference in the etching speed decreases as the concentration of the oxidizing agent increases. In contrast, the etching speed of the polysilicon film decreases as the concentration of the oxidizing agent increases. If the lowering of the anisotropy is prioritized, the concentration of the oxidizing agent may be increased. If the etching speed is prioritized, the concentration of the oxidizing agent may be decreased. Thus, it is possible to control the etching of the polysilicon film by changing the concentration of the oxidizing agent.

Another embodiment of the present invention provides a substrate processing apparatus including a substrate holding unit that holds a substrate on which a polysilicon film and a silicon oxide film are exposed, an etching liquid making unit that makes an alkaline etching liquid containing an organic alkali, an oxidizing agent and a water and not containing a hydrogen fluoride compound by mixing the organic alkali, the oxidizing agent and the water, an etching liquid supplying unit that supplies the etching liquid made by the etching liquid making unit to the substrate held by the substrate holding unit, and a controller that controls the etching liquid making unit and the etching liquid supplying unit.

The controller executes an etching liquid making step of causing the etching liquid making unit to make the etching liquid, and a selectively etching step of causing the etching liquid supplying unit to supply the etching liquid to the substrate and etching the polysilicon film while inhibiting etching the silicon oxide film. According to this arrangement, the same effects as the effects described above regarding the substrate processing method can be obtained.

In the present embodiment, at least one of the following features may be added to the substrate processing apparatus.

The etching liquid making unit is a unit that makes an alkaline liquid consisting of the organic alkali, the oxidizing agent and the water. According to this arrangement, the same effects as the effects described above regarding the substrate processing method can be obtained.

The substrate includes a laminated film including a plurality of polysilicon films and a plurality of silicon oxide films laminated in a thickness direction of the substrate such that the polysilicon films and the silicon oxide films are alternated and a concave portion recessed from an outermost surface of the substrate in the thickness direction of the substrate and penetrating the plurality of the polysilicon films and the plurality of the silicon oxide films, and the etching liquid supplying unit includes a unit that supplies the etching liquid at least to an inside of the concave portion. According to this arrangement, the same effects as the effects described above regarding the substrate processing method can be obtained.

The substrate processing apparatus further includes an oxide film removing liquid supplying unit that supplies an oxide film removing liquid to the substrate held by the substrate holding unit and the controller further executes a natural oxide film removing step of causing the oxide film removing liquid supplying unit to supply the oxide film removing liquid to the substrate and removing a natural oxide film of the polysilicon film before the selectively etching step. According to this arrangement, the same effects as the effects described above regarding the substrate processing method can be obtained.

The polysilicon film is a thin film obtained by performing a plurality of steps including a deposition step of depositing polysilicon and a heat treatment step of heating the polysilicon deposited in the deposition step. According to this arrangement, the same effects as the effects described above regarding the substrate processing method can be obtained.

The etching liquid making unit includes a dissolved oxygen concentration changing unit that lowers dissolved oxygen concentration of the etching liquid. According to this arrangement, the same effects as the effects described above regarding the substrate processing method can be obtained.

The substrate processing apparatus further includes an atmosphere oxygen concentration changing unit that lowers oxygen concentration in an atmosphere that is in contact with the etching liquid held by the substrate. According to this arrangement, the same effects as the effects described above regarding the substrate processing method can be obtained.

The etching liquid making unit includes an oxidizing agent concentration changing unit that changes concentration of the oxidizing agent in the etching liquid. According to this arrangement, the same effects as the effects described above regarding the substrate processing method can be obtained.

The above and other elements, features, steps, characteristics and advantages of the present invention will become more apparent from the following detailed description of the embodiments with reference to the attached drawings.

### BRIEF DESCRIPTION OF THE DRAWINGS

FIG. 1 a schematic view of a substrate processing apparatus according to an embodiment of the present invention when viewed from above.

FIG. 2 a schematic view of the interior of a processing unit included in the substrate processing apparatus when viewed horizontally.

FIG. 3 enlarged view of a portion of FIG. 2.

FIG. 4 a schematic view showing a chemical liquid making unit that makes chemical liquid to be supplied to a substrate and a dissolved oxygen concentration changing unit that adjusts the dissolved oxygen concentration of the chemical liquid.

FIG. 5 a block diagram showing hardware of a controller.

FIG. 6 a schematic view showing an example of a cross-section of the substrate to be processed by the substrate processing apparatus.

FIG. 7 a process chart for describing an example of the processing of the substrate which is executed by the substrate processing apparatus.

FIG. 8 a graph showing a relationship between concentration of hydrogen peroxide in etching liquid and etching speed of each of crystal planes of silicon.

FIG. 9 a schematic view showing a chemical liquid making unit according to another embodiment of the present invention.

### DETAILED DESCRIPTION OF PREFERRED EMBODIMENTS

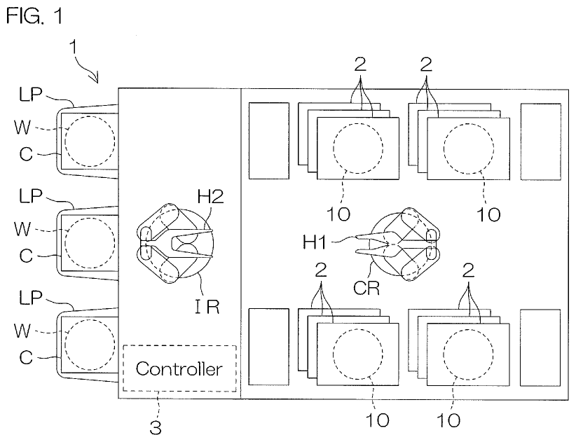

FIG. 1 is a schematic view of a substrate processing apparatus 1 according to an embodiment of the present invention when viewed from above.

The substrate processing apparatus 1 is a single substrate processing-type apparatus which processes disc-shaped substrates W such as semiconductor wafers one by one. The substrate processing apparatus 1 includes load ports LP which hold carriers C that house one or more substrates W constituting a lot, a plurality of processing units 2 which process the substrates W transferred from the carriers C on the load ports LP with a processing fluid such as a processing liquid or a processing gas, transfer robots which transfer the substrates W between the carriers C on the load ports LP and the processing units 2 and a controller 3 which controls the substrate processing apparatus 1.

The transfer robots include an indexer robot IR which carries the substrates W into and out from the carriers C on the load ports LP and a center robot CR which carries the substrates W into and out from the processing units 2. The indexer robot IR transfers the substrates W between the load ports LP and the center robot CR, the center robot CR transfers the substrates W between the indexer robot IR and the processing units 2. The center robot CR and the indexer robot IR include hands H1 and 112 which support the substrates W.

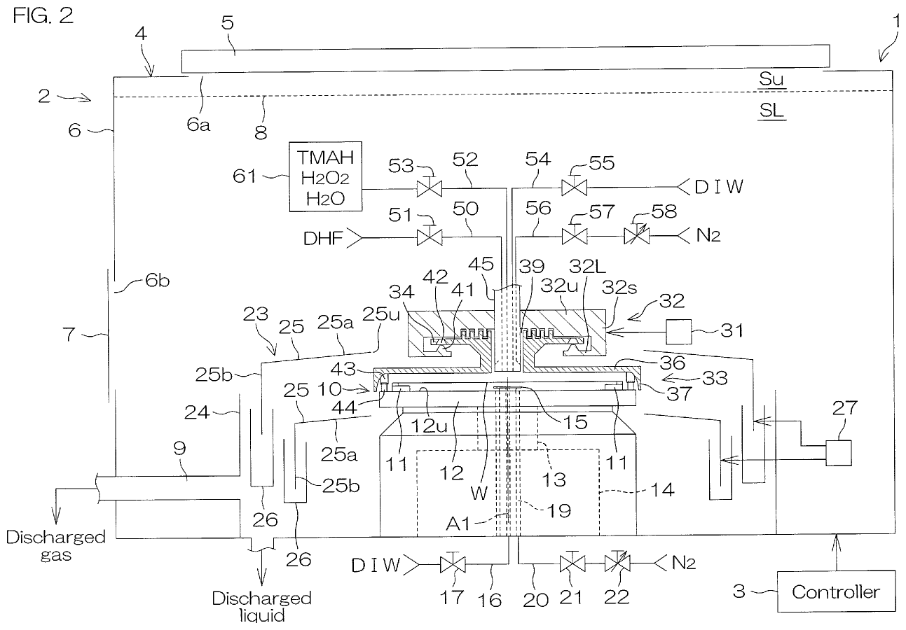

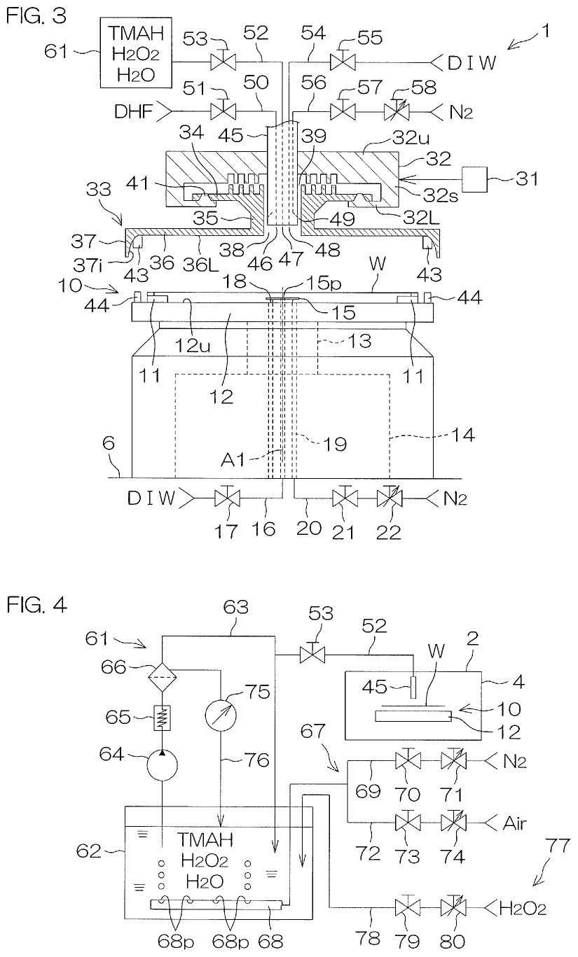

FIG. 2 is a schematic view of the interior of a processing unit 2 included in the substrate processing apparatus 1 when viewed horizontally. FIG. 3 is enlarged view of a portion of FIG. 2.

FIG. 2 shows a state where the raising/lowering frame 32 and the shielding member 33 are located at lower positions and FIG. 3 shows a state where the raising/lowering frame 32 and the shielding member 33 are located at upper positions. In the following description, unless otherwise specified, TMAH represents aqueous solution.

The processing unit 2 includes a box-shaped chamber 4 which has an internal space, a spin chuck 10 which rotates one substrate W around a vertical rotation axis A1 passing through the central portion of the substrate W while holding the substrate W horizontally within the chamber 4 and a tubular processing cup 23 which surrounds the spin chuck 10 around the rotation axis A1.

The chamber 4 includes a box-shaped partition wall 6 provided with a carry-in/carry-out port 6b through which the substrate W passes, and a shutter 7 which opens and closes the carry-in/carry-out port 6b. The chamber 4 further includes a rectifying plate 8 which is arranged below an air outlet 6a that is open in the ceiling surface of the partition wall 6. An FFU 5 (fan filter unit) which feeds clean air (air filtered by a filter) is arranged on the air outlet 6a. An exhaust duct 9 which discharges a gas within the chamber 4 is connected to the processing cup 23. The air outlet 6a is provided in an upper end portion of the chamber 4, and the exhaust duct 9 is arranged in a lower end portion of the chamber 4. A portion of the exhaust duct 9 is arranged outside the chamber 4.

The rectifying plate 8 partitions the internal space of the partition wall 6 into an upper space Su above the rectifying plate 8 and a lower space SL below the rectifying plate 8. The upper space Su between the ceiling surface of the partition wall 6 and the upper surface of the rectifying plate 8 is a diffusion space in which the clean air diffuses. The lower space SL between the lower surface of the rectifying plate 8 and the floor surface of the partition wall 6 is a processing space in which the substrate W is processed. The spin chuck 10 and the processing cup 23 are arranged in the lower space SL. A distance in a vertical direction from the floor surface of the partition wall 6 to the lower surface of the rectifying plate 8 is longer than a distance in the vertical direction from the upper surface of the rectifying plate 8 to the ceiling surface of the partition wall 6.

The FFU 5 feeds the clean air via the air outlet 6a to the upper space Su. The clean air supplied to the upper space Su hits the rectifying plate 8 and diffuses in the upper space Su. The clean air within the upper space Su passes through a plurality of through holes which vertically penetrate the rectifying plate 8, and flows downward from the entire region of the rectifying plate 8. The clean air supplied to the lower space SL is sucked into the processing cup 23 and is discharged through the exhaust duct 9 from the lower end portion of the chamber 4. Thus, a uniform downward flow (down flow) of the clean air which flows downward from the rectifying plate 8 is formed in the lower space SL. The processing of the substrate W is performed in a state where the downward flow of the clean air is formed.

The spin chuck 10 includes a disc-shaped spin base 12 which is held by a horizontal posture, a plurality of chuck pins 11 which hold the substrate W in the horizontal posture above the spin base 12, a spin shaft 13 which extends downward from the central portion of the spin base 12 and a spin motor 14 which rotates the spin shaft 13 so as to rotate the spin base 12 and the chuck pins 11. The spin chuck 10 is not limited to a clamping type chuck which brings the chuck pins 11 into contact with the outer circumferential surface of the substrate W, and the spin chuck 10 may be a vacuum-type chuck which sucks the rear surface (lower surface) of the substrate W that is a non-device formation surface to the upper surface 12u of the spin base 12 so as to hold the substrate W horizontally.

The spin base 12 includes the upper surface 12u which is arranged below the substrate W. The upper surface 12u of the spin base 12 is parallel to the lower surface of the substrate W. The upper surface 12u of the spin base 12 is an opposed surface which faces the lower surface of the substrate W. The upper surface 12u of the spin base 12 has a circular ring shaped configuration which surrounds the rotation axis A1. The outside diameter of the upper surface 12u of the spin base 12 is larger than that of the substrate W. The chuck pins 11 protrude upward from the outer circumferential portion of the upper surface 12u of the spin base 12. The chuck pins 11 are held on the spin base 12. The substrate W is held on the chuck pins 11 in a state where the lower surface of the substrate W is separated from the upper surface 12u of the spin base 12.

The processing unit 2 includes a lower surface nozzle 15 which discharges the processing liquid toward the central portion of the lower surface of the substrate W. The lower surface nozzle 15 includes a nozzle disc portion which is arranged between the upper surface 12u of the spin base 12 and the lower surface of the substrate W and a nozzle tubular portion which extends downward from the nozzle disc portion. The liquid discharge port 15p of the lower surface nozzle 15 is open in the central portion of the upper surface of the nozzle disc portion. In a state where the substrate W is held on the spin chuck 10, the liquid discharge port 15p of the lower surface nozzle 15 faces the central portion of the lower surface of the substrate W.

The substrate processing apparatus 1 includes lower rinse liquid piping 16 which guide a rinse liquid to the lower surface nozzle 15 and a lower rinse liquid valve 17 which is interposed in the lower rinse liquid piping 16. When the lower rinse liquid valve 17 is opened, the rinse liquid guided by the lower rinse liquid piping 16 is discharged upward from the lower surface nozzle 15 and supplied to the central portion of the lower surface of the substrate W. The rinse liquid supplied to the lower surface nozzle 15 is pure water (DIW: deionized water). The rinse liquid supplied to the lower surface nozzle 15 is not limited to pure water, and may be any one of IPA (isopropyl alcohol), carbonated water, electrolytic ion water, hydrogen water, ozone water and a hydrochloric acid water of a dilute concentration (for example, about 1 to 100 ppm).

Although not shown, the lower rinse liquid valve 17 includes a valve body provided with an internal flow path where the liquid flows and an annular valve seat surrounding the internal flow path, a valve member which is movable with respect to the valve seat and an actuator which moves the valve member between a closed position where the valve member contacts the valve seat and an opened position where the valve member is separated from the valve seat. The same applies to other valves. The actuator may be a pneumatic actuator or an electric actuator or an actuator other than those. The controller 3 controls the actuator to open and close the lower rinse liquid valve 17.

The outer circumferential surface of the lower surface nozzle 15 and the inner circumferential surface of the spin base 12 defines a lower tubular path 19 which extends vertically. The lower tubular path 19 includes a lower central opening 18 which is open in the central portion of the upper surface 12u of the spin base 12. The lower central opening 18 is arranged below the nozzle disc portion of the lower surface nozzle 15. The substrate processing apparatus 1 includes lower gas piping 20 which guide an inert gas supplied via the lower tubular path 19 to the lower central opening 18, a lower gas valve 21 which is interposed in the lower gas piping 20 and a lower gas flow rate adjusting valve 22 which changes the flow rate of the inert gas supplied from the lower gas piping 20 to the lower tubular path 19.

The inert gas supplied from the lower gas piping 20 to the lower tubular path 19 is nitrogen gas. The inert gas is not limited to nitrogen gas, and may be another inert gas such as helium gas or argon gas. These inert gases are low oxygen gases which have an oxygen concentration lower than an oxygen concentration (about 21% of the volume) in air.

When the lower gas valve 21 is opened, the nitrogen gas supplied from the lower gas piping 20 to the lower tubular path 19 is discharged upward from the lower central opening 18 at a flow rate corresponding to the degree of opening of the lower gas flow rate adjusting valve 22. Thereafter, the nitrogen gas flows radially in all directions between the lower surface of the substrate W and the upper surface 12u of the spin base 12. Thus, the space between the substrate W and the spin base 12 is filled with the nitrogen gas, and thus an oxygen concentration in an atmosphere is reduced. The oxygen concentration in the space between the substrate W and the spin base 12 is changed according to the degree of opening of the lower gas valve 21 and the lower gas flow rate adjusting valve 22. The lower gas valve 21 and the lower gas flow rate adjusting valve 22 are included in an atmosphere oxygen concentration changing unit that changes oxygen concentration in an atmosphere that is in contact with the substrate W.

The processing cup 23 includes a plurality of guards 25 which receive the liquid discharged outward from the substrate W, a plurality of cups 26 which receive the liquid guided downward by the guards 25 and a cylindrical outer wall member 24 which surrounds the guards 25 and the cups 26. FIG. 2 shows an example where two guards 25 and two cups 26 are provided.

The guard 25 includes a cylindrical guard tubular portion 25b which surrounds the spin chuck 10 and an annular guard ceiling portion 25a which extends obliquely upward from the upper end portion of the guard tubular portion 25b toward the rotation axis A1. Guard ceiling portions 25a vertically overlap each other, and guard tubular portions 25b are arranged concentrically. The cups 26 are arranged below the guard tubular portions 25b, respectively. The cup 26 defines an annular liquid receiving groove which is open upward.

The processing unit 2 includes a guard raising/lowering unit 27 which individually raises and lowers the guards 25. The guard raising/lowering unit 27 locates the guard 25 in an arbitrary position from an upper position to a lower position. The upper position is the position in which the upper end 25u of the guard 25 is arranged higher than a holding position in which the substrate W held by the spin chuck 10 is arranged. The lower position is the position in which the upper end 25u of the guard 25 is arranged lower than the holding position. The annular upper end of the guard ceiling portion 25a corresponds to the upper end 25u of the guard 25. The upper end 25u of the guard 25 surrounds the substrate W and the spin base 12 in plan view.

When the processing liquid is supplied to the substrate W in a state where the spin chuck 10 rotates the substrate W, the processing liquid supplied to the substrate W is spun off around the substrate W. When the processing liquid is supplied to the substrate W, at least one of the upper ends 25u of the guards 25 is arranged higher than the substrate W. Hence, the processing liquid such as the chemical liquid or the rinse liquid which is discharged around the substrate W is received by any one of the guards 25 and guided to the cup 26 corresponding to this guard 25.

As shown in FIG. 3, the processing unit 2 includes the raising/lowering frame 32 which is arranged above the spin chuck 10, the shielding member 33 which is suspended from the raising/lowering frame 32, a center nozzle 45 which is inserted into the shielding member 33 and a shielding member raising/lowering unit 31 which raises and lowers the raising/lowering frame 32 so as to raise and lower the shielding member 33 and the center nozzle 45. The raising/lowering frame 32, the shielding member 33 and the center nozzle 45 are arranged below the rectifying plate 8.

The shielding member 33 includes a disc portion 36 which is arranged above the spin chuck 10 and a tubular portion 37 which extends downward from the outer circumferential portion of the disc portion 36. The shielding member 33 includes an inner surface which has a cup-shaped configuration that is concave upward. The inner surface of the shielding member 33 includes a lower surface 36L of the disc portion 36 and the inner circumferential surface 37i of the tubular portion 37. In the following description, the lower surface 36L of the disc portion 36 may also be referred to as the lower surface 36L of the shielding member 33.

The lower surface 36L of the disc portion 36 is an opposed surface which faces the upper surface of the substrate W. The lower surface 36L of the disc portion 36 is parallel to the upper surface of the substrate W. The inner circumferential surface 37i of the tubular portion 37 extends downward from the outer circumferential edge of the lower surface 36L of the lower surface 36L. The inside diameter of the tubular portion 37 is increased as the lower end of the inner circumferential surface 37i is approached. The inside diameter of the lower end of the inner circumferential surface 37i of the tubular portion 37 is larger than the diameter of the substrate W. The inside diameter of the lower end of the inner circumferential surface 37i of the tubular portion 37 may be larger than the outside diameter of the spin base 12. When the shielding member 33 is arranged in the lower position (position shown in FIG. 2) which will be described below, the substrate W is surrounded by the inner circumferential surface 37i of the tubular portion 37.

The lower surface 36L of the disc portion 36 has a circular ring-shaped configuration which surrounds the rotation axis A1. The inner circumferential edge of the lower surface 36L of the disc portion 36 defines an upper central opening 38 which is open in the central portion of the lower surface 36L of the disc portion 36. The inner circumferential surface of the shielding member 33 defines a through hole which extends upward from the upper central opening 38. The through hole of the shielding member 33 vertically penetrates the shielding member 33. The center nozzle 45 is inserted into the through hole of the shielding member 33. The outside diameter of the lower end of the center nozzle 45 is smaller than the diameter of the upper central opening 38.

The inner circumferential surface of the shielding member 33 is coaxial with the outer circumferential surface of the center nozzle 45. The inner circumferential surface of the shielding member 33 surrounds the outer circumferential surface of the center nozzle 45 across an interval in a radial direction (direction orthogonal to the rotation axis A1). The inner circumferential surface of the shielding member 33 and the outer circumferential surface of the center nozzle 45 define an upper tubular path 39 which extends vertically. The center nozzle 45 protrudes upward from the raising/lowering frame 32 and the shielding member 33. When the shielding member 33 is suspended from the raising/lowering frame 32, the lower end of the center nozzle 45 is arranged higher than the lower surface 36L of the disc portion 36. The processing liquid such as the chemical liquid or the rinse liquid is discharged downward from the lower end of the center nozzle 45.

The shielding member 33 includes a tubular connection portion 35 which extends upward from the disc portion 36, and an annular flange portion 34 which extends outward from the upper end portion of the connection portion 35. The flange portion 34 is arranged higher than the disc portion 36 and the tubular portion 37 of the shielding member 33. The flange portion 34 is parallel to the disc portion 36. The outside diameter of the flange portion 34 is smaller than that of the tubular portion 37. The flange portion 34 is supported on the lower plate 32L of the raising/lowering frame 32 which will be described below.

The raising/lowering frame 32 includes an upper plate 32u which is positioned higher than the flange portion 34 of the shielding member 33, a side ring 32s which extends downward from the upper plate 32u and surrounds the flange portion 34, and an annular lower plate 32L which extends inward from the lower end portion of the side ring 32s and is located below the flange portion 34 of the shielding member 33. The outer circumferential portion of the flange portion 34 is arranged between the upper plate 32u and the lower plate 32L. The outer circumferential portion of the flange portion 34 is movable vertically in a space between the upper plate 32u and the lower plate 32L.

The raising/lowering frame 32 and the shielding member 33 include locating protrusions 41 and locating holes 42 which restrict the relative movement of the raising/lowering frame 32 and the shielding member 33 in a circumferential direction (direction around the rotation axis A1) in a state where the shielding member 33 is supported by the raising/lowering frame 32. FIG. 2 shows an example where a plurality of locating protrusions 41 are provided on the lower plate 32L and where a plurality of locating holes 42 are provided in the flange portion 34. The locating protrusions 41 may be provided on the flange portion 34, and the locating holes 42 may be provided in the lower plate 32L.

The locating protrusions 41 are arranged on a circle which has a center arranged on the rotation axis A1. Similarly, the locating holes 42 are arranged on a circle which has a center arranged on the rotation axis A1. The locating holes 42 are arranged in the circumferential direction with the same regularity as the locating protrusions 41. The locating protrusions 41 which protrude upward from the upper surface of the lower plate 32L are inserted into the locating holes 42 which extend upward from the lower surface of the flange portion 34. Thus, the movement of the shielding member 33 in the circumferential direction with respect to the raising/lowering frame 32 is restricted.

The shielding member 33 includes a plurality of upper support portions 43 which protrude downward from the inner surface of the shielding member 33. The spin chuck 10 includes a plurality of lower support portions 44 which supports the upper support portions 43, respectively. The upper support portions 43 are surrounded by the tubular portion 37 of the shielding member 33. The lower ends of the upper support portions 43 are arranged higher than the lower end of the tubular portion 37. The distance in the radial direction from the rotation axis A1 to the upper support portion 43 is larger than the radius of the substrate W. Similarly, the distance in the radial direction from the rotation axis A1 to the lower support portion 44 is larger than the radius of the substrate W. The lower support portions 44 protrude upward from the upper surface 12u of the spin base 12. The lower support portions 44 are arranged on the outer side with respect to the chuck pins 11.

The upper support portions 43 are arranged on a circle which has a center arranged on the rotation axis A1. Similarly, the lower support portions 44 are arranged on a circle which has a center arranged on the rotation axis A1. The lower support portions 44 are arranged in the circumferential direction with the same regularity as the upper support portions 43. The lower support portions 44 are rotated together with the spin base 12 around the rotation axis A1. The rotational angle of the spin base 12 is changed by the spin motor 14. When the spin base 12 is arranged at a reference rotational angle, the upper support portions 43 respectively overlap the lower support portions 44 in plan view.

The shielding member raising/lowering unit 31 is coupled to the raising/lowering frame 32. When the shielding member raising/lowering unit 31 lowers the raising/lowering frame 32 in a state where the flange portion 34 of the shielding member 33 is supported on the lower plate 32L of the raising/lowering frame 32, the shielding member 33 is also lowered. When the shielding member raising/lowering unit 31 lowers the shielding member 33 in a state where the spin base 12 is arranged at such a reference rotational angle that the upper support portions 43 respectively overlap the lower support portions 44 in plan view, the lower end portions of the upper support portions contact the upper end portions of the lower support portions 44. Thus, the upper support portions 43 are respectively supported on the lower support portions 44.

When the shielding member raising/lowering unit 31 lowers the raising/lowering frame 32 after the upper support portions 43 of the shielding member 33 contact the lower support portions 44 of the spin chuck 10, the lower plate 32L of the raising/lowering frame 32 is moved downward with respect to the flange portion 34 of the shielding member 33. Thus, the lower plate 32L is separated from the flange portion 34, and thus the locating protrusions 41 are removed from the locating holes 42. Furthermore, the raising/lowering frame 32 and the center nozzle 45 are moved downward with respect to the shielding member 33, and thus the difference in height between the lower end of the center nozzle 45 and the lower surface 36L of the disc portion 36 of the shielding member 33 is reduced. Here, the raising/lowering frame 32 is arranged at such a height (the lower position which will be described below) that the flange portion 34 of the shielding member 33 does not contact the upper plate 32u of the raising/lowering frame 32.

The shielding member raising/lowering unit 31 locates the raising/lowering frame 32 in an arbitrary position from the upper position (position shown in FIG. 3) to the lower position (position shown in FIG. 2). The upper position is the position in which the locating protrusions 41 are inserted into the locating holes 42 and in which the flange portion 34 of the shielding member 33 contact the lower plate 32L of the raising/lowering frame 32. In other words, the upper position is the position in which the shielding member 33 is suspended from the raising/lowering frame 32. The lower position is the position in which the lower plate 32L is separated from the flange portion 34 and in which the locating protrusions 41 are removed from the locating holes 42. In other words, the lower position is the position in which the coupling of the raising/lowering frame 32 and the shielding member 33 is released and in which the shielding member 33 does not contact any portion of the raising/lowering frame 32.

When the raising/lowering frame 32 and the shielding member 33 are moved to the lower position, the lower ends of the tubular portion 37 of the shielding member 33 are arranged lower than the lower surface of the substrate W, and thus the space between the upper surface of the substrate W and the lower surface 36L of the shielding member 33 is surrounded by the tubular portion 37 of the shielding member 33. Hence, the space between the upper surface of the substrate W and the lower surface 36L of the shielding member 33 is shielded not only from an atmosphere above the shielding member 33 but also from an atmosphere around the shielding member 33. Thus, it is possible to enhance the sealing performance to seal the space between the upper surface of the substrate W and the lower surface 36L of the shielding member 33.

Furthermore, when the raising/lowering frame 32 and the shielding member 33 are arranged in the lower position, even if the shielding member 33 is rotated around the rotation axis A1, the shielding member 33 is prevented from colliding with the raising/lowering frame 32. When the upper support portions 43 of the shielding member 33 are supported on the lower support portions 44 of the spin chuck 10, the upper support portions 43 and the lower support portions 44 engage with each other, and thus the relative movement of the upper support portions 43 and the lower support portions 44 in the circumferential direction is prevented. When the spin motor 14 rotates in this state, the torque of the spin motor 14 is transmitted to the shielding member 33 via the upper support portions 43 and the lower support portions 44. Thus, the shielding member 33 rotates in the same direction and at the same speed as the spin base 12 in a state where the raising/lowering frame 32 and the center nozzle 45 are stationary.

The center nozzle 45 includes a plurality of liquid discharge ports through which the liquid is discharged and a gas discharge port through which the gas is discharged. The liquid discharge ports include a first chemical liquid discharge port 46 through which a first chemical liquid is discharged, a second chemical liquid discharge port 47 through which a second chemical liquid is discharged and an upper rinse liquid discharge port 48 through which the rinse liquid is discharged. The gas discharge port is an upper gas discharge port 49 through which an inert gas is discharged. The first chemical liquid discharge port 46, the second chemical liquid discharge port 47, the upper rinse liquid discharge port 48 are open in the lower end of the center nozzle 45. The upper gas discharge port 49 is open in the outer circumferential surface of the center nozzle 45.

Each of the first chemical liquid and the second chemical liquid is a liquid which contains at least one of sulfuric acid, nitric acid, hydrochloric acid, hydrofluoric acid, phosphoric acid, acetic acid, ammonia water, hydrogen peroxide water, organic acids (for example, citric acid, oxalic acid), organic alkalis (for example, TMAH: tetramethylammonium hydroxide), a surfactant and a corrosion inhibitor, for example. Sulfuric acid, nitric acid, hydrochloric acid, hydrofluoric acid, phosphoric acid, acetic acid, ammonia water, hydrogen peroxide water, citric acid, oxalic acid and TMAH are etching liquids.

The first chemical liquid and the second chemical liquid may be the same types of chemical liquid or may be different types of chemical liquids. FIG. 2, etc., show an example where the first chemical liquid is DHF (dilute hydrofluoric acid) and where the second chemical liquid is a mixed liquid of TMAH, hydrogen peroxide (H₂O) and water (H₂O). Also, FIG. 2, etc., show the example where the rinse liquid supplied to the center nozzle 45 is pure water and where the inert gas supplied to the center nozzle 45 is nitrogen gas. The rinse liquid supplied to the center nozzle 45 may be a rinse liquid other than pure water. The inert gas supplied to the center nozzle 45 may be an inert gas other than nitrogen gas.

The substrate processing apparatus 1 includes a chemical liquid making unit 61 that makes the second chemical liquid. As described below, the chemical liquid making unit 61 makes an alkaline etching liquid containing TMAH (anhydride of TMAH), the hydrogen peroxide and the water. This etching liquid corresponds to the second chemical liquid. The etching liquid is a liquid with pH (hydrogen-ion exponent) of 12 or more, for example. The etching liquid may contain a component other than TMAH, the hydrogen peroxide and the water.

TMAH is an example of the organic alkali. TMAH is also an example of a solution of quaternary ammonium hydroxide. The organic alkali may be a compound other than TMAH. The organic alkali other than TMAH includes TEAH (Tetraethylammonium Hydroxide), TPAH (Tetrapropylammonium Hydroxide), TBAH (Tetrabutylammonium Hydroxide), and the like. All of these are included in the quaternary ammonium hydroxide.

The hydrogen peroxide is an example of the oxidizing agent. A hydrogen peroxide water (30 vol %) is mixed with TMAH at an inside of a tank 62 described below (refer to FIG. 4). When the volume ratio between the anhydride of TMAH and the water is 1:4 (the water is 4), the volume ratio of the hydrogen peroxide water to be added to TMAH is 0.005 to 1, preferably 0.005 to 0.5, for example. The oxidizing agent may be a liquid or gas other than the hydrogen peroxide. For example, ozone gas, which is an example of the oxidizing agent, may be dissolved in TMAH, instead of the hydrogen peroxide.

The substrate processing apparatus 1 includes first chemical liquid piping 50 which guide the first chemical liquid to the center nozzle 45, a first chemical liquid valve 51 which is interposed in the first chemical liquid piping 50, second chemical liquid piping 52 which guide the second chemical liquid to the center nozzle 45, a second chemical liquid valve 53 which is interposed in the second chemical liquid piping 52, upper rinse liquid piping 54 which guide the rinse liquid to the center nozzle 45 and an upper rinse liquid valve 55 which is interposed in the upper rinse liquid piping 54. The substrate processing apparatus 1 further includes upper gas piping 56 which guide the gas to the center nozzle 45, an upper gas valve 57 which is interposed in the upper gas piping 56 and an upper gas flow rate adjusting valve 58 which changes the flow rate of the gas supplied from the upper gas piping 56 to the center nozzle 45.

When the first chemical liquid valve 51 is opened, the first chemical liquid is supplied to the center nozzle 45 and is discharged downward from the first chemical liquid discharge port 46 which is open in the lower end of the center nozzle 45. When the second chemical liquid valve 53 is opened, the second chemical liquid made by the chemical liquid making unit 61 is supplied to the center nozzle 45 and is discharged downward from the second chemical liquid discharge port 47 which is open in the lower end of the center nozzle 45. When the upper rinse liquid valve 55 is opened, the rinse liquid is supplied to the center nozzle 45 and is discharged downward from the upper rinse liquid discharge port 48 which is open in the lower end of the center nozzle 45. Thus, the chemical liquid or the rinse liquid is supplied to the upper surface of the substrate W.

When the upper gas valve 57 is opened, the nitrogen gas guided by the upper gas piping 56 is supplied to the center nozzle 45 at a flow rate corresponding to the degree of opening of the upper gas flow rate adjusting valve 58 and is discharged obliquely downward from the upper gas discharge port 49 which is open in the outer circumferential surface of the center nozzle 45. Thereafter, the nitrogen gas flows downward within the upper tubular path 39 while flowing in the circumferential direction within the upper tubular path 39. The nitrogen gas that has reached the lower end of the upper tubular path 39 flows downward from the lower end of the upper tubular path 39. Thereafter, the nitrogen gas flows radially in all directions in the space between the upper surface of the substrate W and the lower surface 36L of the shielding member 33. Thus, the space between the substrate W and the shielding member 33 is filled with the nitrogen gas, and the oxygen concentration in the atmosphere is reduced. The oxygen concentration in the space between the substrate W and the shielding member 33 is changed according to the degree of opening of the upper gas valve 57 and the upper gas flow rate adjusting valve 58. The upper gas valve 57 and the upper gas flow rate adjusting valve 58 are included in the atmosphere oxygen concentration changing unit.

FIG. 4 is a schematic view showing a chemical liquid making unit 61 that makes the chemical liquid to be supplied to the substrate W and a dissolved oxygen concentration changing unit 67 that adjusts the dissolved oxygen concentration of the chemical liquid.

The chemical liquid making unit 61 includes the tank 62 that stores the etching liquid to be supplied to the substrate W and circulation piping 63 that form an annular circulation path which circulates the etching liquid in the tank 62. The chemical liquid making unit 61 further includes a pump 64 that sends the etching liquid in the tank 62 to the circulation piping 63 and a filter 66 that removes foreign matters such as particles from the etching liquid flowing through the circulation path. In addition to these, the chemical liquid making unit 61 may include a temperature controller 65 that changes the temperature of the etching liquid in the tank 62 by heating or cooling the etching liquid.

An upstream end and a downstream end of the circulation piping 63 are connected to the tank 62. An upstream end of the second chemical liquid piping 52 is connected to the circulation piping 63, a downstream end of the second chemical liquid piping 52 is connected to the center nozzle 45. The pump 64, temperature controller 65 and the filter 66 are interposed into the circulation piping 63. Temperature controller 65 may be a heater that heats a liquid at a temperature higher than a room temperature (for example, 20 to 30 degrees Celsius), or may be a cooler that cools a liquid at a temperature lower than the room temperature, or may have both heating and cooling functions.

The pump 64 always sends the etching liquid in the tank 62 into the circulation piping 63. The etching liquid flows from the tank 62 to the upstream end of the circulation piping 63 and returns from the downstream end of the circulation piping 63 to the tank 62. Thus, the etching liquid in the tank 62 circulates in the circulation path. The temperature of the etching liquid is adjusted by the temperature controller 65 during the etching liquid is circulating in the circulation path. Thus, the etching liquid in the tank 62 is maintained at a constant temperature. When the second chemical liquid valve 53 is opened, some of the etching liquid flowing through the circulation piping 63 is supplied to the center nozzle 45 via the second chemical liquid piping 52.

The substrate processing apparatus 1 includes the dissolved oxygen concentration changing unit 67 that adjusts the dissolved oxygen concentration of the etching liquid. The dissolved oxygen concentration changing unit 67 includes gas supply piping 68 that dissolve gas in the etching liquid in the tank 62 by supplying gas into the tank 62. The dissolved oxygen concentration changing unit 67 further includes inert gas piping 69 that supply inert gas to the gas supply piping 68, an inert gas valve 70 that opens and closes between an open state in which inert gas flows from the inert gas piping 69 to the gas supply piping 68 and a close state in which inert gas is stopped at the inert gas piping 69, and an inert gas flow rate adjusting valve 71 that changes a flow rate of inert gas to be supplied to the gas supply piping 68 from the inert gas piping 69.

The gas supply piping 68 is a bubbling piping which includes gas discharge ports 68p which are arranged in the etching liquid in the tank 62. When the inert gas valve 70 is opened, that is, when the inert gas valve 70 is switched from the closed state to the opened state, the inert gas such as nitrogen gas is discharged from the gas discharge ports 68p at a flow rate corresponding to the degree of opening of the inert gas flow rate adjusting valve 71. Thus, a large number of air bubbles are formed in the etching liquid in the tank 62, and thus the inert gas is dissolved in the etching liquid in the tank 62. Here, the dissolved oxygen is discharged from the etching liquid, and thus the dissolved oxygen concentration of the etching liquid is lowered. The dissolved oxygen concentration of the etching liquid in the tank 62 is changed by changing the flow rate of the nitrogen gas discharged from the gas discharge ports 68p.

The dissolved oxygen concentration change unit 67 may include, in addition to the inert gas piping 69, etc., an oxygen containing gas piping 72 which supplies an oxygen containing gas containing oxygen such as clean air to the gas supply piping 68, an oxygen containing gas valve 73 which is opened and closed between an opened state where the oxygen containing gas flows from the oxygen containing gas piping 72 to the gas supply piping 68 and a closed state where the oxygen containing gas is stopped at the oxygen containing gas piping 72 and an oxygen containing gas flow rate adjusting valve 74 which changes the flow rate of the oxygen containing gas supplied from the oxygen containing gas piping 72 to the gas supply piping 68.

When the oxygen containing gas valve 73 is opened, air which is an example of the oxygen containing gas is discharged from the gas discharge ports 68p at a flow rate corresponding to the degree of opening of the oxygen containing gas flow rate adjusting valve 74. Thus, a large number of air bubbles are formed in the etching liquid in the tank 62, and thus the air is dissolved in the etching liquid in the tank 62. Air contains oxygen at about 21 vol %, whereas nitrogen gas does not contain oxygen or contains only a very small amount of oxygen. Thus, as compared with a case where the air is not supplied into the tank 62, it is possible to increase the dissolved oxygen concentration of the etching liquid in the tank 62 in a short period of time. For example, when the dissolved oxygen concentration of the etching liquid is excessively lowered with respect to a setting value, the air may be intentionally dissolved in the etching liquid in the tank 62.

The dissolved oxygen concentration change unit 67 may further include an oxygen meter 75 which measures the dissolved oxygen concentration of the etching liquid. FIG. 4 shows an example where the oxygen meter 75 is interposed in a measurement piping 76. The oxygen meter 75 may be interposed in the circulation piping 63. The upstream end of the measurement piping 76 is connected to the filter 66, and the downstream end of the measurement piping 76 is connected to the tank 62. The upstream end of the measurement piping 76 may be connected to the circulation piping 63. Some of the etching liquid within the circulation piping 63 flows into the measurement piping 76 and is returned to the tank 62. The oxygen meter 75 measures the dissolved oxygen concentration of the etching liquid which flows into the measurement piping 76. The degree of opening of at least one of the inert gas valve 70, the inert gas flow rate adjusting valve 71, the oxygen containing gas valve 73 and the oxygen containing gas flow rate adjusting valve 74 is changed according to the measurement value of the oxygen meter 75.

The chemical liquid making unit 61 includes an oxidizing agent concentration changing unit 77 that changes the concentration of the oxidizing agent in the etching liquid. The oxidizing agent concentration changing unit 77 includes oxidizing agent piping 78 that guide the oxidizing agent to be supplied to the tank 62, an oxidizing agent valve 79 that opens and closes the oxidizing agent piping 78, and a flow rate adjusting valve 80 that changes a flow rate of the oxidizing agent to be supplied to the tank 62 from the oxidizing agent piping 78. When the oxidizing agent valve 79 is opened, the hydrogen peroxide water, which is an example of the oxidizing agent, is supplied to the tank 62 at a flow rate corresponding to the degree of opening of the oxidizing agent flow rate adjusting valve 80. The hydrogen peroxide water is mixed with the etching liquid in the tank 62 due to a liquid flow in the tank 62 caused by the suction power of the pump 64 and the supply of gas. The chemical liquid making unit 61 may include a stirrer that stirs the liquid in the tank 62.

The oxidizing agent concentration changing unit 77, which includes the oxidizing agent valve 79 and the oxidizing agent flow rate adjusting valve 80 is controlled by the controller 3. The oxidizing agent valve 79 is closed except when the etching liquid containing TMAH, the hydrogen peroxide and the water is made and except when the concentration of the hydrogen peroxide is changed. In other words, when the etching liquid containing TMAH, the hydrogen peroxide and the water is made and when the concentration of the hydrogen peroxide is changed, the oxidizing agent valve 79 is opened and an appropriate amount of hydrogen peroxide water is supplied into the tank 62. As described below, the concentration of the hydrogen peroxide in the etching liquid is set so that the anisotropy of the silicon single crystal with respect to the etching liquid containing TMAH, the hydrogen peroxide and the water lowers.

FIG. 5 is a block diagram showing hardware of the controller 3.

The controller 3 is a computer which includes a computer main body 81 and a peripheral device 84 which is connected to the computer main body 81. The computer main body 81 includes a CPU 82 (central processing unit) which executes various types of commands and a main storage device 83 which stores information. The peripheral device 84 includes an auxiliary storage device 85 which stores information such as a program P, a reading device 86 which reads information from a removable medium M and a communication device 87 which communicates with other devices such as a host computer.

The controller 3 is connected to an input device 88 and a display 89. The input device 88 is operated when an operator such as a user or a maintenance operator inputs information to the substrate processing apparatus 1. The information is displayed on the screen of the display 89. The input device 88 may be any one of a keyboard, a pointing device and a touch panel or may be a device other than those. A touch panel display which serves both as the input device 88 and the display 89 may be provided in the substrate processing apparatus 1.

The CPU 82 executes the program P stored in the auxiliary storage device 85. The program P within the auxiliary storage device 85 may be previously installed in the controller 3, may be fed through the reading device 86 from the removable medium M to the auxiliary storage device 85 or may be fed from an external device such as the host computer to the auxiliary storage device 85 through the communication device 87.

The auxiliary storage device 85 and the removable medium M are nonvolatile memories which retain memory even without power being supplied. The auxiliary storage device 85 is, for example, a magnetic storage device such as a hard disk drive. The removable medium M is, for example, an optical disc such as a compact disc or a semiconductor memory such as a memory card. The removable medium M is an example of a computer readable recording medium in which the program P is recorded.

The auxiliary storage device 85 stores a plurality of recipes. The recipe is information which specifies the details of processing, processing conditions and processing procedures of the substrate W. A plurality of recipes differ from each other in at least one of the details of processing, the processing conditions and the processing procedures of the substrate W. The controller 3 controls the substrate processing apparatus 1 such that the substrate W is processed according to the recipe designated by the host computer. The controller 3 executes individual steps described below by controlling the substrate processing apparatus 1. In other words, the controller 3 is programmed to execute the individual steps.

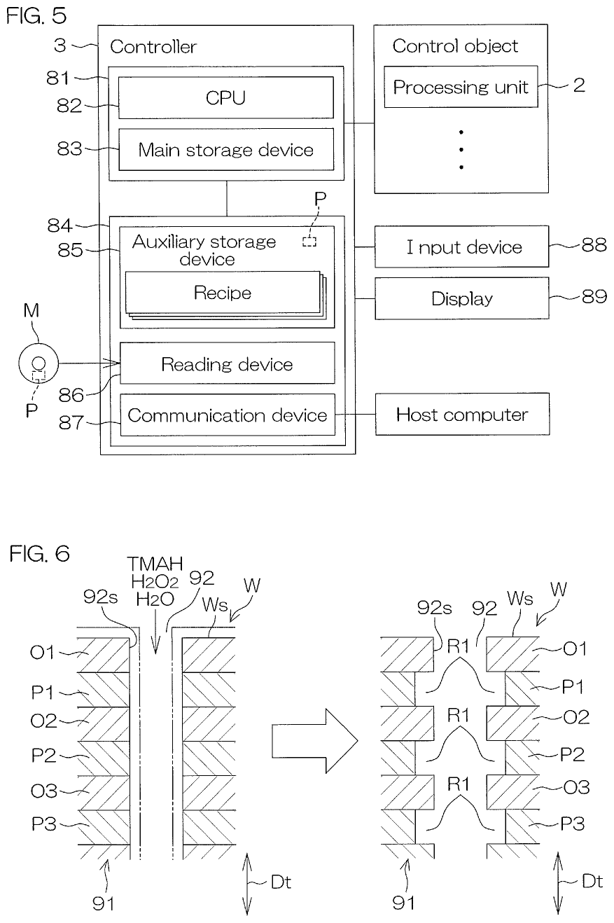

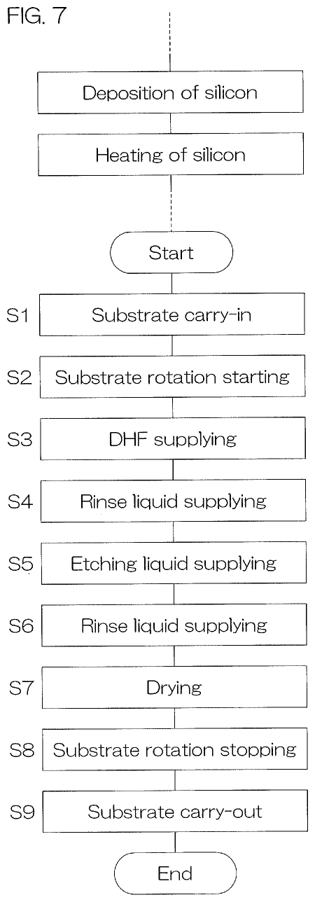

FIG. 6 is a schematic view showing an example of a cross-section of the substrate W to be processed by the substrate processing apparatus 1. FIG. 7 is a process chart for describing an example of the processing of the substrate W which is executed by the substrate processing apparatus 1.

The left side of FIG. 6 shows a cross-section of the substrate W before it is etched and the right side of FIG. 6 shows a cross-section of the substrate W after it is etched. As shown in the right side of FIG. 6, when the substrate W is etched, a plurality of recesses R1 recessed in a plane direction of the substrate W (a direction perpendicular to a thickness direction Dt of the substrate W) are formed on side surfaces 92s of a concave portion 92.

As shown in FIG. 6, the substrate W includes a laminated film 91 formed on a base material such as a silicon wafer and the like, and the concave portion 92 recessed in the thickness direction Dt of the substrate W (a direction perpendicular to the surface of the base material of the substrate) from the outermost surface Ws of the substrate W. The laminated film 91 includes a plurality of polysilicon films P1, P2, P3 and a plurality of silicon oxide films O1, O2, O3.

The plurality of the polysilicon films P1 to P3 and the plurality of the silicon oxide films O1 to O3 are laminated in the thickness direction Dt of the substrate W such that the polysilicon films and the silicon oxide films are alternated. As shown in FIG. 7, the polysilicon films P1 to P3 are thin films for which a deposition step of depositing polysilicon on the substrate W and a heat treatment step of heating the deposited polysilicon are executed. The polysilicon films P1 to P3 may be thin films for which the heat treatment step is not executed.

As shown in FIG. 6, the concave portion 92 penetrates the plurality of the polysilicon films P1 to P3 and the plurality of the silicon oxide films O1 to O3 in the thickness direction Dt of the substrate W. The side surfaces of the polysilicon films P1 to P3 and the silicon oxide films O1 to O3 are exposed at the side surface 92s of the concave portion 92. The concave portion 92 may be any of a trench, a via hole and a contact hole, or may be other than these.

Natural oxide films exist on the surface layers of the polysilicon films P1 to P3 and the silicon oxide films O1 to O3 before the processing by the substrate processing apparatus 1 starts. Alternate long and two short dashes line in the left side of FIG. 6 represents outlines of the natural oxide films. The following describes the processing in which the natural oxide films of the polysilicon films P1 to P3 and the silicon oxide films O1 to O3 are removed by the supply of DHF which is an example of the oxide film removing liquid, and thereafter the polysilicon films P1 to P3 are selectively etched by the supply of the etching liquid.

The following describes an example of the processing of the substrate W executed by the substrate processing apparatus 1, referring to FIG. 1, FIG. 2, FIG. 3 and FIG. 7. Steps after start in FIG. 7 are executed in the substrate processing apparatus 1.

When the substrate W is processed by the substrate processing apparatus 1, a carry-in step of carrying the substrate W into the chamber 4 is performed (step S1 in FIG. 7).

Specifically, in a state where the raising/lowering frame 32 and the shielding member 33 are positioned in the upper position and where all the guards 25 are positioned in the lower position, the center robot CR causes the hand H1 to enter the chamber 4 while supporting the substrate W with the hand H1. Then, the center robot CR places, on the chuck pins 11, the substrate W on the hand H1 with the front surface of the substrate W directed upward. Thereafter, the chuck pins 11 are pressed onto the outer circumferential surface of the substrate W, and thus the substrate W is grasped. The center robot CR places the substrate W on the spin chuck 10 and thereafter retracts the hand H1 from the interior of the chamber 4.

Then, the upper gas valve 57 and the lower gas valve 21 are opened, and thus the upper central opening 38 of the shielding member 33 and the lower central opening 18 of the spin base 12 start the discharge of the nitrogen gas. Thus, the oxygen concentration in the atmosphere in contact with the substrate W is reduced. Furthermore, the shielding member raising/lowering unit 31 lowers the raising/lowering frame 32 from the upper position to the lower position, and the guard raising/lowering unit 27 raises any one of the guards 25 from the lower position to the upper position. Here, the spin base 12 is held at such a reference rotational angle where the upper support portions 43 respectively overlap the lower support portions 44 in plan view. Hence, the upper support portions 43 of the shielding member 33 are supported on the lower support portions 44 of the spin base 12, and the shielding member 33 is separated from the raising/lowering frame 32. Thereafter, the spin motor 14 is driven to start the rotation of the substrate W (step S2 in FIG. 7).

Then, a first chemical liquid supplying step of supplying DHF as an example of the first chemical liquid to the upper surface of the substrate W is performed (step S3 in FIG. 7).

Specifically, in a state where the shielding member 33 is positioned in the lower position, the first chemical liquid valve 51 is opened, and thus the center nozzle 45 starts the discharge of the DHF. The DHF discharged from the center nozzle 45 lands on the central portion of the upper surface of the substrate W and thereafter flows outward along the upper surface of the substrate W which is being rotated. Thus, a liquid film of the DHF which covers the entire region of the upper surface of the substrate W is formed, and the DHF is supplied to the entire region of the upper surface of the substrate W. When a predetermined time elapses after the opening of the first chemical liquid valve 51, the first chemical liquid valve 51 is closed, and the discharge of the DHF is stopped.

Then, a first rinse liquid supplying step of supplying pure water as an example of the rinse liquid to the upper surface of the substrate W is performed (step S4 in FIG. 7).

Specifically, in a state where the shielding member 33 is positioned in the lower position, the upper rinse liquid valve 55 is opened, and thus the center nozzle 45 starts the discharge of the pure water. The pure water which lands on the central portion of the upper surface of the substrate W flows outward along the upper surface of the substrate W that is being rotated. The DHF on the substrate W is rinsed off by the pure water discharged from the center nozzle 45. Thus, a liquid film of the pure water which covers the entire region of the upper surface of the substrate W is formed. When a predetermined time elapses after the opening of the upper rinse liquid valve 55, the upper rinse liquid valve 55 is closed, and the discharge of the pure water is stopped.

Then, a second chemical liquid supplying step of supplying the etching liquid as an example of the second chemical liquid to the upper surface of the substrate W is performed (step S5 in FIG. 7).

Specifically, in a state where the shielding member 33 is positioned in the lower position, the second chemical liquid valve 53 is opened, and thus the center nozzle 45 starts the discharge of the etching liquid. Before the start of the discharge of the etching liquid, in order to switch the guards 25 which receive the liquid discharged from the substrate W, the guard raising/lowering unit 27 may vertically move at least one of the guards 25. The etching liquid which lands on the central portion of the upper surface of the substrate W flows outward along the upper surface of the substrate W that is being rotated. The pure water on the substrate W is replaced by the etching liquid discharged from the center nozzle 45. Thus, a liquid film of the etching liquid which covers the entire region of the upper surface of the substrate W is formed. When a predetermined time elapses after the opening of the second chemical liquid valve 53, the second chemical liquid valve 53 is closed, and the discharge of the etching liquid is stopped.

Then, a second rinse liquid supplying step of supplying pure water as an example of the rinse liquid to the upper surface of the substrate W is performed (step S6 in FIG. 7).

Specifically, in the state where the shielding member 33 is positioned in the lower position, the upper rinse liquid valve 55 is opened, and thus the center nozzle 45 starts the discharge of the pure water. The pure water which lands on the central portion of the upper surface of the substrate W flows outward along the upper surface of the substrate W that is being rotated. The etching liquid on the substrate W is rinsed off by the pure water discharged from the center nozzle 45. Thus, a liquid film of the pure water which covers the entire region of the upper surface of the substrate W is formed. When a predetermined time elapses after the opening of the upper rinse liquid valve 55, the upper rinse liquid valve 55 is closed, and the discharge of the pure water is stopped.

Then, a drying step of drying the substrate W by the rotation of the substrate W is performed (step S7 in FIG. 7).

Specifically, in the state where the shielding member 33 is positioned in the lower position, the spin motor 14 accelerates the substrate W in the rotation direction so as to rotate the substrate W at a high rotational speed (for example, several thousands of rpm) higher than the rotational speed of the substrate Win a period from the first chemical liquid supplying step to the second rinse liquid supplying step. Thus, the liquid is removed from the substrate W, and thus the substrate W is dried. When a predetermined time elapses after the start of the high-speed rotation of the substrate W, the spin motor 14 stops the rotation. Here, the spin motor 14 stops the spin base 12 at the reference rotational angle. Thus, the rotation of the substrate W is stopped (step S8 in FIG. 7).

Then, a carry-out step of carrying the substrate W out from the chamber 4 is performed (step S9 in FIG. 7).

Specifically, the shielding member raising/lowering unit 31 raises the raising/lowering frame 32 to the upper position, and the guard raising/lowering unit 27 lowers all the guards 25 to the lower position. Furthermore, the upper gas valve 57 and the lower gas valve 21 are closed, and thus the upper central opening 38 of the shielding member 33 and the lower central opening 18 of the spin base 12 stop the discharge of the nitrogen gas. Thereafter, the center robot CR causes the hand H1 to enter the chamber 4. After the chuck pins 11 release the grasping of the substrate W, the center robot CR supports the substrate W on the spin chuck 10 with the hand H1. Thereafter, the center robot CR retracts the hand H1 from the interior of the chamber 4 while supporting the substrate W with the hand H1. Thus, the processed substrate W is carried out from the chamber 4.

FIG. 8 is a graph showing a relationship between the concentration of the hydrogen peroxide in the etching liquid and an etching speed of each of crystal planes of silicon. The etching speed (an etching amount per unit time) corresponds to an etching rate.

A vertical line in FIG. 8 represents the etching speed and A horizontal line in FIG. 8 represents the concentration of the hydrogen peroxide. Circle mark, triangle mark and square mark in FIG. 8 represent the etching speeds of Si (110) plane, Si (100) plane and Si (111) plane, respectively. The maximum difference in the description below means a difference between the maximum value and the minimum value of the etching speeds of Si (110) plane, Si (100) plane and Si (111) plane. That is, the maximum difference means the anisotropy of the etching speed (the difference between the etching speeds in plane directions).

The circle mark, the triangle mark and the square mark in FIG. 8 located at the vertical line show the etching speeds of Si (110) plane, Si (100) plane and Si (111) plane when the hydrogen peroxide is not added to the etching liquid, i.e. when the concentration of the hydrogen peroxide is zero. when the concentration of the hydrogen peroxide is zero, the circle mark is the largest and the square mark is the smallest. The triangle mark is located on the circle mark side.

When the concentration of the hydrogen peroxide is the concentration 1, that is, the hydrogen peroxide is added to the etching liquid, any of the circle mark, the triangle mark and the square mark significantly decrease as compared to a case where the etching liquid is not added. The maximum difference when the concentration of the hydrogen peroxide is the concentration 1 significantly decrease as compared to the maximum difference when the concentration of the hydrogen peroxide is zero. In the concentration 1, the triangle mark is the largest and the square mark is the smallest. The circle mark is located near the triangle mark.

When the concentration of the hydrogen peroxide is the concentration 2 that is higher than the concentration 1, as compared to the concentration 1, any of the circle mark, the triangle mark and the square mark decrease. the maximum difference when the concentration of the hydrogen peroxide is the concentration 2 is smaller than the maximum difference when the concentration of the hydrogen peroxide is the concentration 1. In the concentration 2, the triangle mark is the largest and the circle mark is the smallest. The square mark is located near the triangle mark. The square mark is located around the middle between the triangle mark and the circle mark.

When the concentration of the hydrogen peroxide is the concentration 3 that is higher than the concentration 2, the circle mark, the triangle mark and the square mark have almost the same value and overlap each other. As compared to the concentration 2, the triangle mark and the square mark decrease and the circle mark slightly increases. The maximum difference when the concentration of the hydrogen peroxide is the concentration 3 is smaller than the maximum difference when the concentration of the hydrogen peroxide is the concentration 2.

According to the measured results in FIG. 8, when the hydrogen peroxide is added to the etching liquid consisting of TMAH and the water, the etching speeds of Si (110) plane, Si (100) plane and Si (111) plane decrease. The maximum difference of the etching speeds decreases as the concentration of the hydrogen peroxide increases. In other words, the anisotropy of silicone lowers as the concentration of the hydrogen peroxide increases. The etching speed of each of the crystal planes tends to decrease as the concentration of the hydrogen peroxide increases.

According to the above analysis, it is possible to lower the anisotropy of silicon single crystal with respect to the etching liquid by adding the hydrogen peroxide to the etching liquid consisting of TMAH and the water. Furthermore, it is possible to further lower the anisotropy of silicon single crystal by increasing the concentration of the hydrogen peroxide. However, since the etching speed of the entire polysilicon films P1 to P3 decreases when the concentration of the hydrogen peroxide is too high, the concentration of the hydrogen peroxide may be determined depending on which of the anisotropy and the etching rate is prioritized.

As described above, in the embodiment, the alkaline etching liquid containing TMAH, the hydrogen peroxide and the water is supplied to the substrate W on which the polysilicon films P1 to P3 and the silicon oxide films O1 to O3 are exposed. The etching liquid is liquid that etches polysilicon and does not or hardly etches silicon oxide. The etching speed of the silicon oxide is smaller than the etching speed of the polysilicon. Thus, it is possible to selectively etch the polysilicon films P1 to P3.

The etching liquid supplied to the substrate W touches the surface of the polysilicon films P1 to P3. The surface of polysilicon film is composed of many minute silicon single crystals. The hydrogen peroxide contained in the etching liquid reacts with the surfaces of the many minute silicon single crystals and forms silicon oxides. Thus, when the hydrogen peroxide is added to the etching liquid, the etching speed of the polysilicon films P1 to P3 gets lower.

However, the hydrogen peroxide contained in the etching liquid does not uniformly reacts with a plurality of crystal planes of silicon single crystal, but preferentially reacts with one of these crystal planes, which has a higher activation energy. Thus, the etching speed of the crystal plane with high activation energy decreases relatively greatly, and thus the difference in the etching speed between plane directions decreases. It lowers anisotropy of silicon single crystal with respect to the etching liquid. That is, the etching of the silicon single crystals composing the polysilicon films P1 to P3 approaches isotropic.

Furthermore, the etching liquid does not contain the hydrogen fluoride compound. The hydrogen fluoride compound reacts with the silicon oxide films O1 to O3 and dissolves the silicon oxide films O1 to O3 in the etching liquid. The silicon oxide formed by the reaction between the polysilicon films P1 to P3 and the hydrogen peroxide also reacts with the hydrogen fluoride compound and dissolves in the etching liquid. Thus, it is possible to prevent the selectivity (the etching speed of the polysilicon films P1 to P3/the etching speed of the silicon oxide films O1 to O3) from lowering and to prevent the effect due to the hydrogen peroxide from lowering by removing the hydrogen fluoride compound from the components of the etching liquid. Accordingly, it is possible to uniformly etch the polysilicon films P1 to P3 while inhibiting etching the silicon oxide films O1 to O3.

In the embodiment, the alkaline etching liquid containing only TMAH, the hydrogen peroxide and the water and containing no other component is supplied to the substrate W on which the polysilicon films P1 to P3 and the silicon oxide films O1 to O3 are exposed. Thus, it is possible to decrease the difference in the etching speed between plane directions of silicon single crystal and to lower anisotropy of the silicon single crystals composing the polysilicon films P1 to P3 with respect to the etching liquid. Accordingly, it is possible to uniformly etch the polysilicon films P1 to P3 while inhibiting etching the silicon oxide films O1 to O3.

In the embodiment, the side surfaces of the polysilicon films P1 to P3 and the silicon oxide films O1 to O3 included in the laminated film 91 are exposed in the side surface 92s of the concave portion 92 formed in the substrate W. The etching liquid is supplied to the inside of the concave portion 92 of the substrate W. Thus, the side surfaces of the plurality of the polysilicon films P1 to P3s are etched and moved in the plane direction of the substrate W (so-called side etching). That is, a plurality of recesses R1 recessed from the side surfaces of the plurality of the silicon oxide films O1 to O3 in the plane direction of the substrate W are formed in the concave portion 92.

If the anisotropy of the silicon single crystal with respect to the etching liquid is high, the etching speed of the polysilicon films P1 to P3 is slightly different for each polysilicon film. In this case, the depth (the distance in the plane direction of the substrate W) of the recess R1 formed in the concave portion 92 is different for each recess R1. Thus, it is possible to decrease the difference in the etching speed between the plurality of the polysilicon films P1 to P3s and to reduce the variation in depth of the recess R1 by including the hydrogen peroxide in the etching liquid.

In the embodiment, DHF, which is an example of the oxide film removing liquid, is supplied to the substrate W and the natural oxide film of the polysilicon films P1 to P3 is removed from the surface layer of the polysilicon films P1 to P3. After that, the etching liquid is supplied to the substrate W and the polysilicon films P1 to P3 is selectively etched. The natural oxide film of the polysilicon films P1 to P3 is mainly composed of silicon oxide. The etching liquid is liquid that etches polysilicon and does not or hardly etches silicon oxide. Thus, it is possible to effectively etch the polysilicon films P1 to P3 by removing the natural oxide film of the polysilicon films P1 to P3 in advance.

In the embodiment, the polysilicon films P1 to P3, for which the heat treatment step to heat the deposited polysilicon is executed, is etched by the alkaline etching liquid containing the hydrogen peroxide. When the deposited polysilicon is heated under an appropriate condition, the grain size of the polysilicon increases. Thus, as compared with the case where the heat treatment step is not executed, the silicon single crystals composing the polysilicon films P1 to P3 increase in size. It means that the number of the silicon single crystals exposed on the surface of the polysilicon films P1 to P3 decreases and the influence of the anisotropy increases. Thus, it is possible to effectively lower the influence of the anisotropy by supplying the etching liquid including the hydrogen peroxide to such polysilicon film.

In the embodiment, the etching liquid the dissolved oxygen concentration of which is lowered is supplied to the substrate W. As described above, the hydrogen peroxide lowers the anisotropy of the silicon single crystals composing the polysilicon films P1 to P3, but decreases the etching speed of the polysilicon films P1 to P3. On the other hand, when the dissolved oxygen concentration of the etching liquid is lowered, the etching speed of the polysilicon films P1 to P3 increases. Thus, it is possible to lower the anisotropy of the silicon single crystal while reducing the decrease in the etching speed of the polysilicon films P1 to P3 by supplying the substrate W with the etching liquid the dissolved oxygen concentration of which is lowered.

In the embodiment, the etching liquid is supplied to the substrate W in a state where the oxygen concentration in the atmosphere. Thus, the amount of the oxygen dissolved in the etching liquid from the atmosphere decreases and the rise in the dissolved oxygen concentration is reduced. As described above, the hydrogen peroxide lowers the anisotropy of the silicon single crystals composing the polysilicon films P1 to P3, but decreases the etching speed of the polysilicon films P1 to P3. If the dissolved oxygen concentration of the etching liquid increases, the etching speed of the polysilicon films P1 to P3 further decreases. Thus, it is possible to reduce the further decrease in the etching speed by lowering the oxygen concentration in the atmosphere.

In the embodiment, the concentration of the hydrogen peroxide in the etching liquid is changed. When the hydrogen peroxide is added to etching liquid containing TMAH and the water even in a very small amount, the difference in the etching speed between the plurality of the crystal planes decreases and the anisotropy of the silicon single crystals composing the polysilicon films P1 to P3 is lowered. The difference in the etching speed decreases as the concentration of the hydrogen peroxide increases. In contrast, the etching speed of the polysilicon films P1 to P3 decreases as the concentration of the hydrogen peroxide increases. If the lowering of the anisotropy is prioritized, the concentration of the hydrogen peroxide may be increased. If the etching speed is prioritized, the concentration of the hydrogen peroxide may be decreased. Thus, it is possible to control the etching of the polysilicon films P1 to P3 by changing the concentration of the hydrogen peroxide.

### Other Embodiments

The present invention is not restricted to the contents of the embodiments described above and various modifications are possible.

For example, TMAH and the hydrogen peroxide water may be mixed not at the inside of the tank 62 but at a position between the tank 62 and the discharge port of the center nozzle 45. Specifically, the oxidizing agent piping 78 that guide the hydrogen peroxide water, which is an example of the oxidizing agent, may be connected not to the tank 62 but to a path of the chemical liquid from the tank 62 to the discharge port 47 of the center nozzle 45.

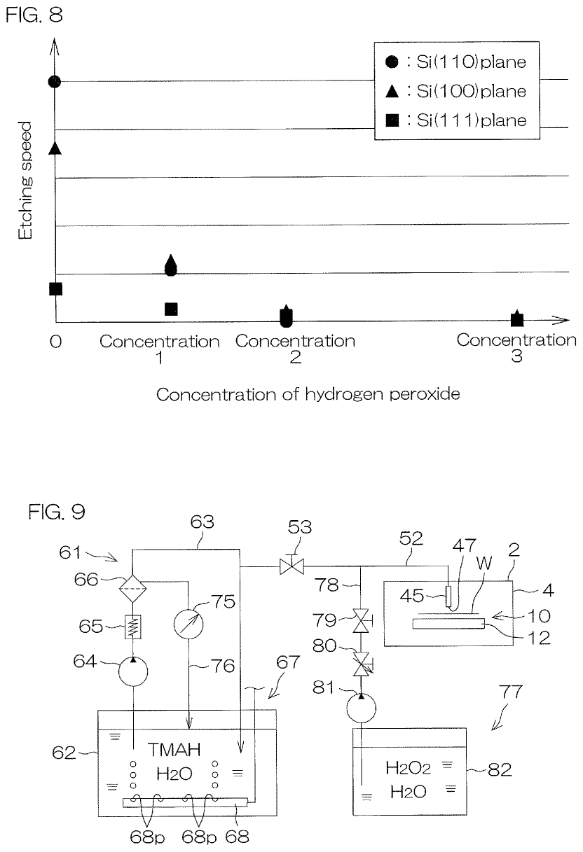

For example, as shown in FIG. 9, the oxidizing agent piping 78 may be connected to the second chemical liquid piping 52, or the oxidizing agent piping 78 may be connected to the center nozzle 45. In these cases, the hydrogen peroxide water is send by a pump 81 from a tank 82 to the oxidizing agent piping 78 and mixed with TMAH at the inside of the second chemical liquid piping 52 or the inside of the center nozzle 45. Thus, the alkaline etching liquid containing TMAH, the hydrogen peroxide and the water is discharged from the discharge port 47 of the center nozzle 45.

When TMAH and the hydrogen peroxide water are mixed, TMAH may deteriorate. Even in the case, it is possible to reduce the degree of deterioration of TMAH by mixing TMAH and the hydrogen peroxide water immediately before the etching liquid is supplied to the substrate W. It is possible to further reduce the degree of deterioration of TMAH by mixing TMAH and the hydrogen peroxide water not at the inside of the second chemical liquid piping 52 but at the inside of the center nozzle 45. On the other hand, it is possible to supply the uniform etching liquid to the substrate W by mixing TMAH and the hydrogen peroxide water not at the inside of the center nozzle 45 but at the inside of the second chemical liquid piping 52, as compared to a case of mixing in the center nozzle 45.

The etching liquid such as TMAH may be supplied not to the upper surface of the substrate W but to the lower surface of the substrate W. Alternatively, the etching liquid may be supplied to both the upper surface and the lower surface of the substrate W. In these cases, the lower surface nozzle 15 may be used to discharge the etching liquid.

The dissolved oxygen concentration changing unit 67 may be omitted from the substrate processing apparatus 1. That is, the etching liquid the dissolved oxygen concentration of which is not lowered may be supplied to the substrate W.

The concentration of the hydrogen peroxide in the etching liquid may be changed by supplying at least one of TMAH and the water to the inside of the tank 62 in addition to or instead of supplying the hydrogen peroxide water to the tank 62.

The tubular portion 37 may be omitted from the shielding member 33. The upper support portions 43 and the lower support portions 44 may be omitted from the shielding member 33 and spin chuck 10.

The shielding member 33 may be omitted from the processing unit 2. In this case, the processing unit 2 may include a nozzle that discharges the processing liquid such as the first chemical liquid toward the substrate W. The nozzle may be a scan nozzle that is horizontally movable in the chamber 4, or may be a fixed nozzle that is fixed with respect to the partition wall 6 of the chamber 4. The nozzle may include a plurality of liquid discharge ports that supply the processing liquid to the upper surface or the lower surface of the substrate W by simultaneously discharging the processing liquid toward a plurality of positions away in the radial direction of the substrate W. In this case, at least one of the flow rate, the temperature and the concentration of the processing liquid to be discharged may be changed for each of the liquid discharge ports.

The number of the polysilicon films included in the laminated film 91 may be one. Similarly, the number of the silicon oxide films included in the laminated film 91 may be one.

In a case where the silicon oxide film is formed on the polysilicon film, the concave portion 92 may penetrate only the silicon oxide film in the thickness direction Dt of the substrate W. That is, the surface of the polysilicon film may be a bottom surface of the concave portion 92. In this case, a plurality of concave portions 92 may be provided in the substrate W.

The substrate processing apparatus 1 is not restricted to an apparatus for processing a disc-shaped substrate W, and may be an apparatus for processing a polygonal substrate W.

The substrate processing apparatus 1 may be a batch type apparatus that processes a plurality of substrates at once.

Two or more arrangements among all the arrangements described above may be combined. Two or more steps among all the steps described above may be combined.

This application corresponds to Japanese Patent Application No. 2018-038993 filed in the Japan Patent Office on Mar. 5, 2018, and the entire disclosure of this application is incorporated herein by reference.

The embodiments of the present invention are described in detail above, however, these are just detailed examples used for clarifying the technical contents of the present invention, and the present invention should not be limitedly interpreted to these detailed examples, and the spirit and scope of the present invention should be limited only by the claims appended hereto.

### REFERENCE SIGNS LIST

1: substrate processing apparatus
3: controller
10: spin chuck (substrate holding unit)
15: lower surface nozzle (etching liquid supplying unit)
21: lower gas valve (atmosphere oxygen concentration changing unit)
22: lower gas flow rate adjusting valve (atmosphere oxygen concentration changing
unit)
45: center nozzle
46: first chemical liquid discharge port (oxide film removing liquid supplying unit)
47: second chemical liquid discharge port (etching liquid supplying unit)
57: upper gas valve (atmosphere oxygen concentration changing unit)
58: upper gas flow rate adjusting valve (atmosphere oxygen concentration changing unit)
61: chemical liquid making unit (etching liquid making unit)
67: dissolved oxygen concentration changing unit (dissolved oxygen concentration changing unit)
77: oxidizing agent concentration changing unit (oxidizing agent concentration changing unit)
79: oxidizing agent valve (oxidizing agent concentration changing unit)
80: flow rate adjusting valve (oxidizing agent concentration changing unit)
91: laminated film
92: concave portion
92s: side surface of concave portion
Dt: thickness direction of substrate
O1, O2, O3: silicon oxide film
P1, P2, P3: polysilicon film
W: the substrate
Ws: outermost surface

1. A substrate processing method comprising:
an etching liquid making step of making an alkaline etching liquid containing an organic alkali, an oxidizing agent and a water and not containing a hydrogen fluoride compound by mixing the organic alkali, the oxidizing agent and the water;
a selectively etching step of supplying the etching liquid made in the etching liquid making step to a substrate on which a polysilicon film and a silicon oxide film are exposed and etching the polysilicon film while inhibiting etching the silicon oxide film.

2. The substrate processing method according to claim 1, wherein
the etching liquid making step is a step of making an alkaline liquid consisting of the organic alkali, the oxidizing agent and the water.

3. The substrate processing method according to claim 1, wherein
the substrate includes a laminated film including a plurality of polysilicon films and a plurality of silicon oxide films laminated in a thickness direction of the substrate such that the polysilicon films and the silicon oxide films are alternated and a concave portion recessed from an outermost surface of the substrate in the thickness direction of the substrate and penetrating the plurality of the polysilicon films and the plurality of the silicon oxide films, and
the selectively etching step includes a step of supplying the etching liquid at least to an inside of the concave portion.

4. The substrate processing method according to claim 1, further comprising a natural oxide film removing step of supplying an oxide film removing liquid to the substrate and removing a natural oxide film of the polysilicon film before the selectively etching step.

5. The substrate processing method according to claim 1, wherein
the polysilicon film is a thin film obtained by performing a plurality of steps including a deposition step of depositing polysilicon and a heat treatment step of heating the polysilicon deposited in the deposition step.

6. The substrate processing method according to claim 1, wherein
the etching liquid making step includes a dissolved oxygen concentration changing step of lowering dissolved oxygen concentration of the etching liquid.

7. The substrate processing method according to claim 1, further comprising an atmosphere oxygen concentration changing step of lowering oxygen concentration in an atmosphere that is in contact with the etching liquid held by the substrate.

8. The substrate processing method according to claim 1, wherein
the etching liquid making step includes an oxidizing agent concentration changing step of changing concentration of the oxidizing agent in the etching liquid.

9. A substrate processing apparatus comprising:
a substrate holding unit that holds a substrate on which a polysilicon film and a silicon oxide film are exposed;
an etching liquid making unit that makes an alkaline etching liquid containing an organic alkali, an oxidizing agent and a water and not containing a hydrogen fluoride compound by mixing the organic alkali, the oxidizing agent and the water;
an etching liquid supplying unit that supplies the etching liquid made by the etching liquid making unit to the substrate held by the substrate holding unit; and
a controller that controls the etching liquid making unit and the etching liquid supplying unit, wherein
the controller executes
an etching liquid making step of causing the etching liquid making unit to make the etching liquid, and
a selectively etching step of causing the etching liquid supplying unit to supply the etching liquid to the substrate and etching the polysilicon film while inhibiting etching the silicon oxide film.

10. The substrate processing apparatus according to claim 9, wherein
the etching liquid making unit is a unit that makes an alkaline liquid consisting of the organic alkali, the oxidizing agent and the water.

11. The substrate processing apparatus according to claim 9, wherein
the substrate includes a laminated film including a plurality of polysilicon films and a plurality of silicon oxide films laminated in a thickness direction of the substrate such that the polysilicon films and the silicon oxide films are alternated and a concave portion recessed from an outermost surface of the substrate in the thickness direction of the substrate and penetrating the plurality of the polysilicon films and the plurality of the silicon oxide films, and
the etching liquid supplying unit includes a unit that supplies the etching liquid at least to an inside of the concave portion.

12. The substrate processing apparatus according to claim 9, wherein
the substrate processing apparatus further comprises an oxide film removing liquid supplying unit that supplies an oxide film removing liquid to the substrate held by the substrate holding unit and
the controller further executes a natural oxide film removing step of causing the oxide film removing liquid supplying unit to supply the oxide film removing liquid to the substrate and removing a natural oxide film of the polysilicon film before the selectively etching step.

13. The substrate processing apparatus according to claim 9, wherein
the polysilicon film is a thin film obtained by performing a plurality of steps including a deposition step of depositing polysilicon and a heat treatment step of heating the polysilicon deposited in the deposition step.

14. The substrate processing apparatus according to claim 9, wherein
the etching liquid making unit includes a dissolved oxygen concentration changing unit that lowers dissolved oxygen concentration of the etching liquid.

15. The substrate processing apparatus according to claim 9, further comprising an atmosphere oxygen concentration changing unit that lowers oxygen concentration in an atmosphere that is in contact with the etching liquid held by the substrate.

16. The substrate processing apparatus according to claim 9, wherein
the etching liquid making unit includes an oxidizing agent concentration changing unit that changes concentration of the oxidizing agent in the etching liquid.
